(19) United States
(12) Patent Application Publication
(10) Pub. No.: US 2023/0253458 A1
(43) Pub. Date: Aug. 10, 2023

(54) SILICON CARBIDE SEMICONDUCTOR DEVICE AND METHOD OF MANUFACTURING SILICON CARBIDE SEMICONDUCTOR DEVICE

(71) Applicant: FUJI ELECTRIC CO., LTD., Kawasaki-shi (JP)

(72) Inventors: Shinichiro MATSUNAGA, Matsumoto-city (JP); Masakazu BABA, Tsukuba-shi (JP); Shinsuke HARADA, Tsukuba-shi (JP)

(73) Assignee: FUJI ELECTRIC CO., LTD., Kawasaki-shi (JP)

(21) Appl. No.: 18/091,089

(22) Filed: Dec. 29, 2022

(30) Foreign Application Priority Data
Feb. 7, 2022 (JP) 2022-017530

(51) Int. Cl. H01L 29/16; H01L 29/423

(52) U.S. Cl. CPC H01L 29/1608; H01L 29/4236

(57) ABSTRACT

A semiconductor device has: a silicon carbide semiconductor substrate of a first conductivity type; a first semiconductor layer of the first conductivity type; a first semiconductor region of a second conductivity type; a second semiconductor region of the first conductivity type; a trench; a gate insulating film; a gate electrode; a third semiconductor region of the first conductivity type, and a fourth semiconductor region of the second conductivity type. The third semiconductor region is provided between the gate insulating film on a sidewall of the trench and the first semiconductor region. The fourth semiconductor region is provided between the first semiconductor region and the third semiconductor region, and has an impurity concentration higher than that of the first semiconductor region.

### CROSS REFERENCE TO RELATED APPLICATIONS

This application is based upon and claims the benefit of priority of the prior Japanese Patent Application No. 2022-017530, filed on Feb. 7, 2022, the entire contents of which are incorporated herein by reference.

### BACKGROUND OF THE INVENTION

### 1. Field of the Invention

Embodiments of the invention relate to a silicon carbide semiconductor device and a method of manufacturing a silicon carbide semiconductor device.

### 2. Description of the Related Art

Silicon carbide (SiC) is expected to replace silicon (Si) as a next generation semiconductor material. Compared to a conventional semiconductor device element using silicon as a semiconductor material, a semiconductor device element using silicon carbide as a semiconductor material (hereinafter, silicon carbide semiconductor device) has various advantages such as enabling resistance of a device element in an ON state to be reduced to a few hundredths and application under higher temperature (at least 200 degrees C.) environments. These advantages are due to characteristics of the material itself in that a bandgap of silicon carbide is about 3 times larger than that of silicon and dielectric breakdown field strength thereof is nearly an order of magnitude greater than that of silicon.

Up to now, Schottky barrier diodes (SBDs) and vertical metal oxide semiconductor field effect transistors (MOSFETs) having a trench gate structure or planar gate structure have become commercialized as silicon carbide semiconductor devices.

A planar gate structure is a MOS gate structure in which a MOS gate is provided in a flat plate-like shape on a front surface of a semiconductor substrate. A trench gate structure is a MOS gate structure in which a MOS gate is embedded in a trench formed in a semiconductor substrate (semiconductor chip), at a front surface thereof and a channel (inversion layer) is formed along a sidewall of the trench in a direction orthogonal to the front surface of the semiconductor substrate. Therefore, compared to the planar gate structure in which a channel is formed along the front surface of the semiconductor substrate, unit cell (constituent unit of device element) density per unit area as well as current density per unit area may be increased, which are advantageous in terms of cost.

A structure of a conventional silicon carbide semiconductor device is described taking a trench-type SiC-MOSFET as an example. FIG. 8 is a cross-sectional view depicting a structure of the conventional silicon carbide semiconductor device. FIG. 8 depicts a unit cell (functional unit of a device element) structure disposed in an active region through which current flows during an ON state. As depicted in FIG. 8, in a conventional semiconductor device 200, an n-type drift layer 102 is deposited on a front surface of an n⁺-type silicon carbide semiconductor substrate 101. A MOS gate structure is provided in a first side of the n-type drift layer 102. The MOS gate structure is formed by a p-type base region 103, an n⁺-type source region 104, a p⁺-type contact region 114, a trench 105, a gate insulating film 107, and a gate electrode 108. The n⁺-type source region 104 and the p⁺-type contact region 114 are selectively provided in the p-type base region 103.

The trench 105 penetrates through the n⁺-type source region 104 and the p-type base region 103 in a depth direction and reaches the n-type drift layer 102. The gate electrode 108 is provided in the trench 105. The gate electrode 108 faces the p-type base region 103 and the n⁺-type source region 104, with the gate insulating film 107 provided at a bottom and sidewalls of the trench 105 intervening therebetween. In a surface layer of the n-type drift layer 102, a first p-type region 115 is provided between the trench 105 and an adjacent trench 105. Further, in the n-type drift layer 102, a second p-type base region 116 is selectively provided so as to underlie the entire bottom of the trench 105.

In the conventional semiconductor device 200, the p-type base region 103 has a relatively high concentration or channel implantation is performed in the entire surface, whereby leakage between the source and drain during forward bias and reverse bias is suppressed. Further, to suppress saturation current increases and leakage current increases due to a short channel effect when drain voltage becomes high, a high-concentration p-type channel layer 117 having a concentration higher than that of the p-type base region 103 is provided near the channel. Further, by forming the high-concentration p-type channel layer 117 near the channel by channel implantation of the entire surface before the trench 105 is formed, channel threshold is adjusted and channel leakage penetrating through the p-type base region 103 may be suppressed.

FIG. 9 is a cross-sectional view depicting another structure of the conventional silicon carbide semiconductor device. As depicted in FIG. 9, in a conventional semiconductor device 210, provision of a high-concentration p-type region 118 near the trench 105 to suppress application of high electric field to the bottom of the trench 105 when the drain voltage becomes high is commonly known (for example, refer to Japanese Patent No. 6416143). Application of high electric field to the gate insulating film 107 may be suppressed by forming the high-concentration p-type region 118 close to the trench 105 but apart from the p-type base region 103, by oblique implantation.

Further, a silicon carbide semiconductor device is commonly known in which a p-type region is provided adjacent to the gate insulating film, an n⁺-type source region is isolated from the gate insulating film by the p-type region, and a contact area between an n-type source resistance region and the gate insulating film is reduced (for example, refer to Japanese Laid-Open Patent Publication No. 2021-150405). Further, a semiconductor device is commonly known in which a third p⁺-type region is provided in a p-type base region to be apart from but parallel to a trench sidewall, whereby a p-type impurity concentration of a portion of the p-type base region (portion facing the trench sidewall with a channel region intervening therebetween) may be increased and spreading of a depletion layer from the drain side to the source side in each p-type base region when the MOSFET is on may be suppressed (for example, refer to Japanese Laid-Open Patent Publication No. 2019-050352).

### SUMMARY OF THE INVENTION

According to an embodiment of the invention, a silicon carbide semiconductor device includes: a silicon carbide semiconductor substrate of a first conductivity type, the silicon carbide semiconductor substrate having a main surface; a first semiconductor layer of the first conductivity type, provided on the main surface of the silicon carbide semiconductor substrate, the first semiconductor layer having a first surface and a second surface opposite to each other, the second surface of the first semiconductor layer facing the silicon carbide semiconductor substrate, the first semiconductor layer having an impurity concentration that is lower than an impurity concentration of the silicon carbide semiconductor substrate; a first semiconductor region of a second conductivity type, provided at the first surface of the first semiconductor layer, the first semiconductor region having a first surface and a second surface opposite to each other, the second surface of the first semiconductor region facing the silicon carbide semiconductor substrate; a second semiconductor region of the first conductivity type, selectively provided in the first semiconductor region, at the first surface of the first semiconductor region; a trench that penetrates through the first semiconductor region and the second semiconductor region, and reaches the first semiconductor layer; a gate insulating film provided in the trench, along a bottom and a sidewall of the trench; a gate electrode provided in the trench, on the gate insulating film; a third semiconductor region of the first conductivity type, provided between the first semiconductor region and the gate insulating film provided along the sidewall of the trench; and a fourth semiconductor region of the second conductivity type, provided between the first semiconductor region and the third semiconductor region, the fourth semiconductor region having an impurity concentration that is higher than an impurity concentration of the first semiconductor region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a silicon carbide semiconductor device according to an embodiment.

FIG. 2 is a graph depicting withstand voltage waveforms of the silicon carbide semiconductor device according to the embodiment.

FIG. 3 is a graph depicting ON resistance with respect to threshold voltages of the silicon carbide semiconductor device according to the embodiment and a conventional silicon carbide semiconductor device.

FIG. 4 is a cross-sectional view of a state of the silicon carbide semiconductor device according to the embodiment, during manufacture.

FIG. 5 is a cross-sectional view of a state of the silicon carbide semiconductor device according to the embodiment, during manufacture.

FIG. 6 is a cross-sectional view of a state of the silicon carbide semiconductor device according to the embodiment, during manufacture.

FIG. 7 is a cross-sectional view of a state of the silicon carbide semiconductor device according to the embodiment, during manufacture.

FIG. 8 is a cross-sectional view depicting a structure of the conventional silicon carbide semiconductor device.

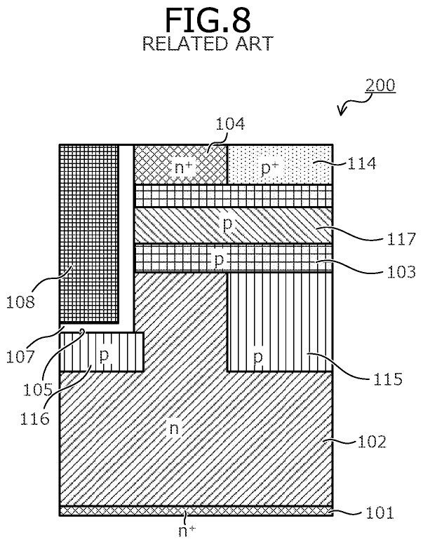

FIG. 9 is a cross-sectional view depicting another structure of the conventional silicon carbide semiconductor device.

### DETAILED DESCRIPTION OF THE INVENTION

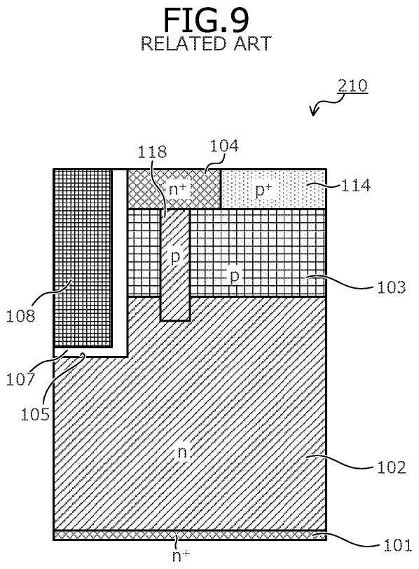

First, problems associated with the conventional techniques are discussed. In the conventional silicon carbide semiconductor device, when the concentration of the p-type base region 103 is not increased to a certain extent, leakage between the source and drain during reverse bias cannot be suppressed. Further, as depicted in FIG. 9, to dispose the high-concentration p-type region 118 close to a pole of the channel, oblique implantation with respect to the trench 105 is necessary, however, in the oblique implantation, the implanted impurity stays close to the channel, whereby the entire area of the p-type base region 103 cannot be set to a high-concentration p-type region.

Embodiments of a silicon carbide semiconductor device and a method of manufacturing a silicon carbide semiconductor device according to the present invention are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and will not be repeatedly described. Further, in the present description, when Miller indices are described, “−” means a bar added to an index immediately after the “−”, and a negative index is expressed by prefixing “−” to the index. Further, with consideration of variation in manufacturing, description indicating the same or equal may be within 5%.

A semiconductor device according to the present invention is configured using a wide bandgap semiconductor. In the embodiment, as a wide bandgap semiconductor, a silicon carbide semiconductor device manufactured (fabricated) using, for example, silicon carbide (SiC) is described taking a trench-type MOSFET 100 as an example.

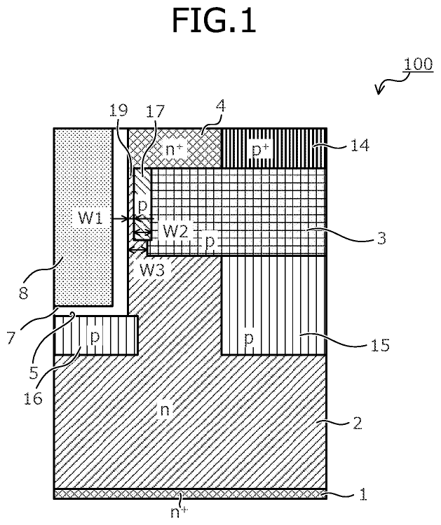

FIG. 1 is a cross-sectional view depicting the structure of a silicon carbide semiconductor device according to the embodiment. As depicted in FIG. 1, in the silicon carbide semiconductor device according to the embodiment, at a first main surface (front surface) of an n⁺-type silicon carbide semiconductor substrate (silicon carbide semiconductor substrate of a first conductivity type) 1, an n-type drift layer (first semiconductor layer of the first conductivity type) 2 is provided. In the n-type drift layer 2, at a first side thereof opposite to a second side thereof facing the n⁺-type silicon carbide semiconductor substrate 1, a MOS gate structure of a trench gate structure is provided. The MOS gate structure is formed by a p-type base region (first semiconductor region of a second conductivity type) 3, an n⁺-type source region (second semiconductor region of the first conductivity type) 4, a trench 5, a gate insulating film 7, and a gate electrode 8. A p⁺-type contact region 14 may be provided. The trench 5, for example, as depicted in FIG. 1, has a stripe-like shape. In FIG. 1, only an active region through which a main current of the trench-type MOSFET 100 flows is depicted.

In the n-type drift layer 2, a second p-type region 16 is selectively provided separate from the p-type base region 3. The second p-type region 16 may be embedded in the n-type drift layer 2 so as to surround a bottom of the trench 5 or face the gate electrode 8 with the gate insulating film 7 intervening therebetween. In other words, the bottom of the trench 5 may be positioned in the second p-type region 16. A width of the second p-type region 16 is wider than a width of the trench 5. The second p-type region 16 has a function of mitigating electric field applied to the n-type drift layer 2. The second p-type region 16, for example, may be a diffused region formed by ion implantation.

A first p-type region 15 is provided in a surface layer of the n-type drift layer 2, between the trench 5 and an adjacent trench 5. The first p-type region 15 is provided at a same depth as that of the second p-type region 16 and has a same potential as that of the p-type base region 3. The first p-type region 15, similarly to the second p-type region 16, has a function of mitigating electric field applied to the n-type drift layer 2.

The first p-type region 15 and the second p-type region 16 are set to have the same potential and thus, the first p-type region 15 and the second p-type region 16 may be connected by extending a portion of the first p-type region 15. The p-type base region 3 is provided on the n-type drift layer 2. The p-type base region 3 is a diffused region formed by ion implantation in a surface layer of the n-type drift layer 2, for example.

In the embodiment, the p-type base region 3 and a channel implantation layer 17 are provided separate from the gate insulating film 7 of the sidewall of the trench 5. Between the gate insulating film 7 at the sidewall of the trench 5 and the p-type base region 3, an n-type region (third semiconductor region of the first conductivity type) 19 of a same impurity concentration as that of the n-type drift layer 2 is provided close to a pole of the gate insulating film 7. A width W1 of the n-type region 19 in a direction in which the trenches 5 are arranged (direction orthogonal to the sidewall of the trench 5) is more than 0 nm but not more than about 50 nm. Therefore, a range of W1 close to the pole of the gate insulating film 7 of the sidewall of the trench 5 is the n-type region. As a result, electrons do not travel only at the gate insulating film 7 interface and thus, decreases in channel mobility may be prevented. The sidewall of the trench 5 is an n-type and electrons may travel in this portion, which thus becomes a channel (accumulation layer) during an ON state. Furthermore, induction of the channel is easier than for a p-type at an equivalent positive gate bias. Further, due to gate potential and the high-concentration channel implantation layer 17 close to the interface, the n-type close to the interface is depleted and therefore, no channel is formed and even in an instance of an n-type, a threshold does not become 0V or less (no depletion).

Further, between the n-type region 19 and the p-type base region 3, the channel implantation layer 17 (fourth semiconductor region of the second conductivity type) having a higher impurity concentration than that of the p-type base region 3 is provided close to the gate insulating film 7. A width W2 of the channel implantation layer 17 in the direction in which the trenches 5 are arranged is greater than 10 nm but not more than about 200 nm. Therefore, a range of W2 close to the gate insulating film 7 of the sidewall of the trench 5 is the p-type region having a higher impurity concentration than that of the p-type base region 3. As a result, the threshold of the semiconductor device may be increased. Further, the impurity concentration of the channel implantation layer 17 is, for example, at least 1×10¹⁸/cm³.

Further, the p-type base region 3 is provided in a region that is apart from the gate insulating film 7 of the sidewall of the trench 5 by at least W3 (about 100 nm) and the p-type base region 3 has a high p-type concentration. As a result, leakage of a portion of the p-type base region 3 may be suppressed. The impurity concentration of the p-type base region 3 is, for example, at least 5×10¹⁶/cm³.

Thus, such a structure is assumed, whereby in the embodiment, without decreases in the electron mobility of the channel, the threshold may be increased and leakage may be suppressed. Therefore, with the high threshold as is, channel mobility may be increased, whereby ON resistance may be reduced and reduced conduction loss becomes possible while malfunction during switching due to lowering of the threshold is suppressed.

The n⁺-type source region 4 is selectively provided in the p-type base region 3. The n⁺-type source region 4 may be an epitaxial layer, for example, or may be a diffused region formed by ion implantation. The p⁺-type contract region 14 may be selectively provided in the p-type base region 3. The n⁺-type source region 4 is in contact with the gate insulating film 7 and the p⁺-type contract region 14 is provided at a position apart from the gate insulating film 7. The trench 5 penetrates through the n⁺-type source region 4 and the p-type base region 3, and reaches the n-type drift layer 2.

The gate electrode 8 faces the second p-type region 16, the p-type base region 3, the n⁺-type source region 4, the channel implantation layer 17, and the n-type drift layer 2 with the gate insulating film 7, which is provided at the bottom and sidewalls of the trench 5, intervening therebetween. An end of the gate electrode 8 facing the drain is positioned closer to the drain than is a pn junction between the p-type base region 3 and the n-type drift layer 2.

A source electrode (not depicted) is in contact with the p-type base region 3 and the n⁺-type source region 4 and is electrically insulated from the gate electrode 8 by a non-depicted interlayer insulating film. In an instance in which the p⁺-type contract region 14 is provided, the source electrode is in contact with the p⁺-type contract region 14 and the n⁺-type source region 4.

At a second main surface (back surface) of the n⁺-type silicon carbide semiconductor substrate 1, a drain electrode constituting a back electrode (not depicted) is provided. At a surface of the back electrode, a drain electrode pad (not depicted) is provided.

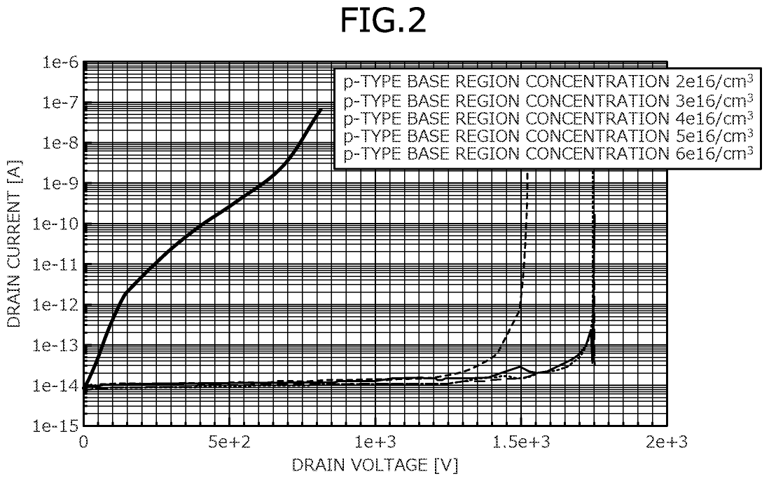

FIG. 2 is a graph depicting withstand voltage waveforms of the silicon carbide semiconductor device according to the embodiment. In FIG. 2, a horizontal axis indicates drain voltage in units of V. A vertical axis indicates drain current in units of A. FIG. 2 shows withstand voltage when the impurity concentration of the p-type base region 3 is varied in a range of 2×10¹⁶/cm³ to 6×10¹⁶/cm³ and as depicted in FIG. 2, when the impurity concentration is at least 4×10¹⁶/cm³, high withstand voltage is maintained.

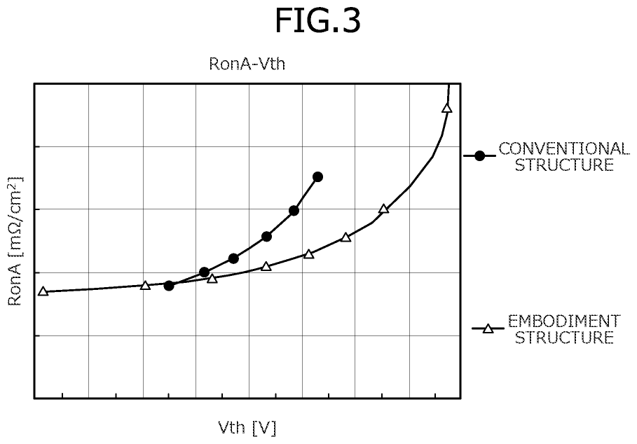

FIG. 3 is a graph depicting ON resistance with respect to threshold voltages of the silicon carbide semiconductor device according to the embodiment and the conventional silicon carbide semiconductor device. In FIG. 3, a horizontal axis indicates threshold (Vth) in units of V. A vertical axis indicates ON resistance (RonA) in units of mfg/cm². As depicted in FIG. 3, in the silicon carbide semiconductor device according to the embodiment, ON resistance may be reduced more than that of the conventional silicon carbide semiconductor device while the high threshold is kept as is.

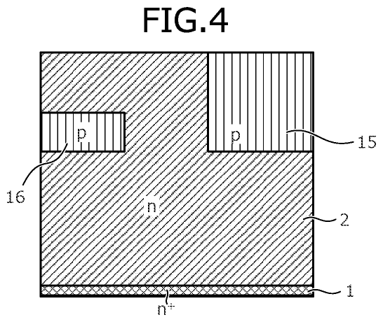

Next, a method of manufacturing the silicon carbide semiconductor device according to the embodiment is described. FIGS. 4, 5, 6, and 7 are cross-sectional views of states of the silicon carbide semiconductor device according to the embodiment, during manufacture.

First, an n⁺-type silicon carbide substrate 1 containing an n-type silicon carbide is prepared. Next, on a front surface (first main surface) of the n⁺-type silicon carbide substrate 1, a first n-type drift layer (not depicted) containing silicon carbide is epitaxially grown while an n-type impurity, for example, nitrogen atoms (N), is doped.

Next, on the surface of the first n-type drift layer, a non-depicted mask having predetermined openings is formed by a photolithographic technique using, for example, an oxide film. Further, a p-type impurity such as aluminum is ion-implanted in the openings of the oxide film, whereby a lower first p-type base region (not depicted) and the second p-type base region 16 are formed. Next, the ion implantation mask is removed. Next, on the surface of the first n-type drift layer, a second n-type drift layer (not depicted) doped with an n-type impurity such as nitrogen is formed.

Next, on the surface of the second n-type drift layer, an ion implantation mask having predetermined openings is formed by photolithography using, for example, an oxide film. Further, a p-type impurity such as aluminum is ion-implanted in openings of the oxide film, whereby upper first p-type base regions (not depicted) are formed so as to overlap the lower first p-type base regions. One of the lower first p-type base regions and an overlapping one of the upper first p-type base regions form a connected region constituting the first p-type region 15. Next, the ion implantation mask is removed. The state up to here is depicted in FIG. 4.

Next, on the surface of the second n-type drift layer, a third n-type drift layer (not depicted) doped with an n-type impurity such as nitrogen is formed. Hereinafter, the first n-type drift layer, the second n-type drift layer, and the third n-type drift layer combined constitute the n-type drift layer 2.

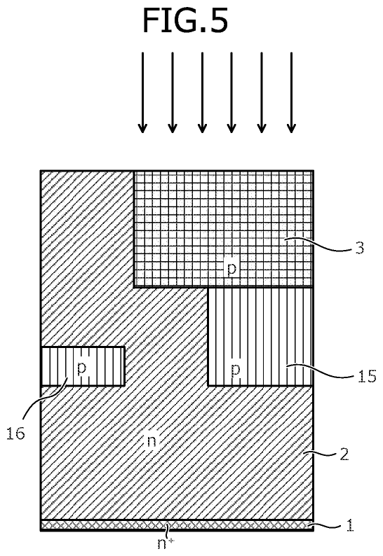

Next, on the surface of the third n-type drift layer, an ion implantation mask having predetermined openings is formed by photolithography using, for example, an oxide film. Further, a p-type impurity such as aluminum is ion-implanted in the openings of the oxide film, thereby selectively forming the p-type base region 3 in portions of the third n-type drift layer, at the surface of the third n-type drift layer. Here, the impurity is implanted so that an n-type region is left between the p-type base region 3 and the gate insulating film 7 at the sidewall of the trench 5. Next, the ion implantation mask is removed. The state up to here is depicted in FIG. 5.

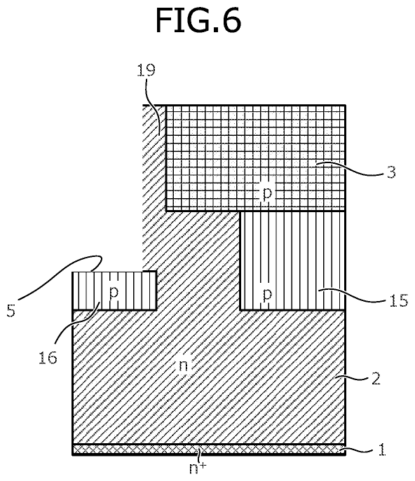

Next, on the surface of the p-type base region 3, a trench formation mask having predetermined openings is formed by photolithography using, for example, an oxide film. Next, each trench 5, which penetrates through the p-type base region 3 and reaches the n-type drift layer 2, is formed by dry etching. The bottom of the trench 5 may reach the second p-type base region 16 formed in the n-type drift layer 2. Next, the trench formation mask is removed. The n-type region of the sidewall of the trench 5 constitutes the n-type region 19. The state up to here is depicted in FIG. 6.

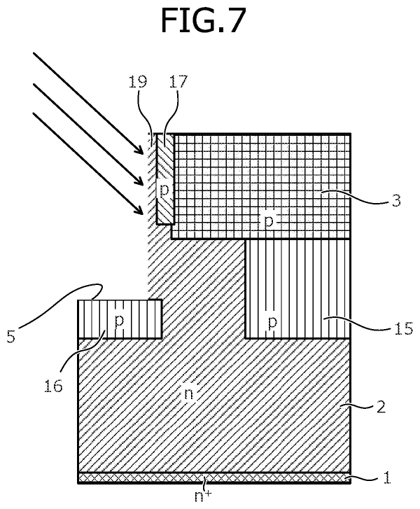

Next, a p-type impurity such as aluminum is ion-implanted obliquely in the p-type base region 3 from the sidewall of the trench 5, whereby the channel implantation layer 17 is formed. The state up to here is depicted in FIG. 7.

Next, on the surface of the p-type base region 3, an ion implantation mask having predetermined openings is formed by photolithography using, for example, an oxide film. An n-type impurity such as nitrogen (N), phosphorus (P), etc. is ion-implanted in the openings, whereby the n⁺-type source region 4 is formed in a portion of each p-type base region 3. Next, the ion implantation mask used in the formation of the n⁺-type source region 4 is removed and by a similar method, an ion implantation mask having predetermined openings is formed, a p-type impurity such as boron is ion-implanted in a portion of each p-type base region 3, at the surface thereof, whereby the p⁺-type contract region 14 is formed. An impurity concentration of the p⁺-type contract region 14 is set to be higher than the impurity concentration of the p-type base region 3.

Next, a heat treatment (activation annealing) for activating all regions formed by ion implantation is performed. For example, a heat treatment (annealing) is performed under an inert gas atmosphere of about 1700 degrees C., whereby an activation process of the p-type base region 3, the first p-type region 15, the second p-type base region 16, the n⁺-type source region 4, the p⁺-type contract region 14, and the channel implantation layer 17 is implemented. As described above, ion implanted regions may be collectively activated by a single session of the heat treatment or may be activated by performing the heat treatment each time ion implantation is performed.

Next, along the surface of each n⁺-type source region 4 and the bottom and the sidewalls of each trench 5, the gate insulating film 7 is formed. First, an oxide film is deposited under an oxygen atmosphere by thermal oxidation at a temperature pf about 1000 degrees C. or by a chemical reaction (chemical vapor deposition) such as that for a high temperature oxide (HTO).

Next, sacrificial oxidation for rounding corners of the bottom of each trench 5 and an opening portion thereof may be performed. Next, an annealing treatment is performed with respect to the oxide film. Thus, the gate insulating film 7 is formed.

Next, on the gate insulating film 7, a multi-crystalline silicon layer doped with, for example, phosphorus atoms is provided. The multi-crystalline silicon layer may be formed so as to be embedded in the trench 5. The multi-crystalline silicon layer is patterned by photolithography and left in each trench 5, whereby the gate electrode 8 is formed.

Next, as depicted, for example, the interlayer insulating film such as a BPSG film is deposited so as to cover each gate electrode 8. Next, the interlayer insulating film is patterned, thereby exposing the n⁺-type source regions 4 and the p⁺-type contract regions 14. Next, in the contact hole, for example, by a sputtering technique, the source electrode (not depicted) is formed so as to be in contact with the n⁺-type source region 4 and the p⁺-type contract region 14.

Next, on the entire back surface of the semiconductor substrate, the back electrode (not depicted) is formed. Thereafter, the semiconductor wafer is cut (diced) into individual chips, whereby the trench-type MOSFET 100 depicted in FIG. 1 is completed.

As described above, according to the embodiment, the range close to the pole of the gate insulating film of the sidewall of the trench is an n-type region and the range close to gate insulating film of the sidewall of the trench is a p-type region having an impurity concentration higher than that of the p-type base region; the p-type base region being provided in a region apart from the gate insulating film of the sidewall of the trench by at least about 100 nm and increasing the p-type concentration of the p-type base region. As a result, without decreases in the electron mobility of the channel, the threshold may be increased and leakage may be suppressed. Therefore, with the high threshold as is, channel mobility may be increased, whereby ON resistance may be reduced and reduced conduction loss becomes possible while malfunction during switching due to lowering of the threshold is suppressed.

In the foregoing, the present invention may be variously modified within a range not departing from the spirit of the invention and, for example, in the embodiment described above, dimensions, impurity concentrations, etc. of regions may be variously set according to necessary specifications. Further, in the embodiments, while the first conductivity type is an n-type and the second conductivity type is a p-type, the present invention is similarly implemented when the first conductivity type is a p-type and the second conductivity type is an n-type.

According to the invention described above, the range close to the pole of the gate insulating film of the sidewall of the trench is an n-type region and the range close to gate insulating film of the sidewall of the trench is a p-type region having an impurity concentration higher than that of the p-type base region; the p-type base region being provided in a region apart from the gate insulating film of the sidewall of the trench by at least about 100 nm and increasing the p-type concentration of the p-type base region. As a result, without decreases in the electron mobility of the channel, the threshold may be increased and leakage may be suppressed. Therefore, with the high threshold as is, channel mobility may be increased, whereby ON resistance may be reduced and reduced conduction loss becomes possible while malfunction during switching due to lowering of the threshold is suppressed.

The silicon carbide semiconductor device and the method of manufacturing a silicon carbide semiconductor device according to the present invention achieve an effect in that with the high threshold as is, channel mobility is increased and channel leakage may be suppressed.

In this manner, the silicon carbide semiconductor device and the method of manufacturing a silicon carbide semiconductor device according to the present invention is useful for power semiconductor devices used in power converting equipment such as inverters, power source devices such as those of various types of industrial machines, igniters of automotive vehicles, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a silicon carbide semiconductor substrate of a first conductivity type, the silicon carbide semiconductor substrate having a main surface;
a first semiconductor layer of the first conductivity type, provided on the main surface of the silicon carbide semiconductor substrate, the first semiconductor layer having a first surface and a second surface opposite to each other, the second surface of the first semiconductor layer facing the silicon carbide semiconductor substrate, the first semiconductor layer having an impurity concentration that is lower than an impurity concentration of the silicon carbide semiconductor substrate;
a first semiconductor region of a second conductivity type, provided at the first surface of the first semiconductor layer, the first semiconductor region having a first surface and a second surface opposite to each other, the second surface of the first semiconductor region facing the silicon carbide semiconductor substrate;
a second semiconductor region of the first conductivity type, selectively provided in the first semiconductor region, at the first surface of the first semiconductor region;
a trench that penetrates through the first semiconductor region and the second semiconductor region, and reaches the first semiconductor layer;
a gate insulating film provided in the trench, along a bottom and a sidewall of the trench;
a gate electrode provided in the trench, on the gate insulating film;
a third semiconductor region of the first conductivity type, provided between the first semiconductor region and the gate insulating film provided along the sidewall of the trench; and
a fourth semiconductor region of the second conductivity type, provided between the first semiconductor region and the third semiconductor region, the fourth semiconductor region having an impurity concentration that is higher than an impurity concentration of the first semiconductor region.

2. The silicon carbide semiconductor device according to claim 1, wherein
the third semiconductor region has a width, in a direction orthogonal to the sidewall of the trench, greater than 0 nm but not more than 50 nm,
the fourth semiconductor region has a width in the direction orthogonal to the sidewall of the trench, greater than 10 nm but not more than 200 nm, and
the first semiconductor region is apart from the gate insulating film of the sidewall of the trench, with a distance of at least 100 nm therebetween in the direction orthogonal to the sidewall of the trench.

3. The silicon carbide semiconductor device according to claim 2, wherein
the impurity concentration of the fourth semiconductor region is at least 1×10¹⁸/cm³, and
the impurity concentration of the first semiconductor region is at least 5×10¹⁶/cm³.

4. A method of manufacturing a silicon carbide semiconductor device, the method comprising:
preparing a silicon carbide semiconductor substrate of a first conductivity type, the silicon carbide semiconductor substrate having a main surface;
forming a first semiconductor layer of the first conductivity type on the main surface, the first semiconductor layer having a first surface and a second surface opposite to each other, the second surface of the first semiconductor layer facing the silicon carbide semiconductor substrate, the first semiconductor layer having an impurity concentration that is lower than an impurity concentration of the silicon carbide semiconductor substrate;
forming a first semiconductor region of a second conductivity type, a second semiconductor region of the first conductivity type, and a third semiconductor region of the first conductivity type, by
ion-implanting an impurity to thereby form the first semiconductor region and the third semiconductor region at the first surface of the first semiconductor layer, the first semiconductor region having a first surface and a second surface opposite to each other, the second surface of the first semiconductor region facing the silicon carbide semiconductor substrate, and
selectively forming the second semiconductor region in the first semiconductor region, at the first surface of the first semiconductor region;
forming a trench that penetrates through the first semiconductor region and the second semiconductor region and reaches the first semiconductor layer;
obliquely ion-implanting an impurity from a sidewall of the trench, thereby forming a fourth semiconductor region of the second conductivity type, between the first semiconductor region and the third semiconductor region, the fourth semiconductor region having an impurity concentration that is higher than an impurity concentration of the first semiconductor region;
forming a gate insulating film in the trench, along a bottom and the sidewall of the trench; and
forming a gate electrode in the trench, on the gate insulating film, wherein
the third semiconductor region is formed between the first semiconductor region and the gate insulating film formed along the sidewall of the trench.
